(19) United States
(12) Patent Application Publication
(10) Pub. No.: US 2003/0010454 A1
(43) Pub. Date: Jan. 16, 2003

(54) Method and apparatus for varying a magnetic field to control a volume of a plasma

(76) Inventors: Andrew D. Bailey III, Pleasanton, CA (US); David J. Hemker, San Jose, CA (US)

Correspondence Address: BEYER WEAVER & THOMAS LLP, P.O. BOX 778, BERKELEY, CA, 94704-0778, US

(21) Appl. No.: 09/536,000

(22) Filed: Mar. 27, 2000

(51) Int. Cl. C23C 16/00; H01L 21/306; C23F 1/00

(52) U.S. Cl. 156/345.49; 118/723 I; 315/111.41

(57) ABSTRACT

A plasma confinement arrangement for controlling the volume of a plasma while processing a substrate inside a process chamber includes a chamber within which a plasma is both ignited and sustained for processing. The chamber is defined at least in part by a wall and further includes a plasma confinement arrangement. The plasma confinement arrangement includes a magnetic array disposed around the periphery of the process chamber configured to produce a magnetic field which establishes a cusp pattern on the wall of the chamber. The cusp pattern on the wall of the chamber defines areas where a plasma might damage or create cleaning problems. The cusp pattern is shifted to improve operation of the substrate processing system and to reduce the damage and/or cleaning problems caused by the plasma's interaction with the wall. Shifting of the cusp pattern can be accomplished by either moving the magnetic array or by moving the chamber wall. Movement of either component may be continuous (that is, spinning one or more magnet elements or all or part of the wall) or incremental (that is, periodically shifting the position of one or more magnet elements or all or part of the wall).

### BACKGROUND OF THE INVENTION

The present invention relates to apparatus and methods for processing substrates such as semiconductor substrates for use in IC fabrication or glass panels for use in flat panel display applications. More particularly, the present invention relates to controlling a plasma inside a plasma process chamber.

Plasma processing systems have been around for some time. Over the years, plasma processing systems utilizing inductively coupled plasma sources, electron cyclotron resonance (ECR) sources, capacitive sources, and the like, have been introduced and employed to various degrees to process semiconductor substrates and glass panels.

During processing, multiple deposition and/or etching steps are typically employed. During deposition, materials are deposited onto a substrate surface (such as the surface of a glass panel or a wafer). For example, deposited layers such as SiO₂ may be formed on the surface of the substrate. Conversely, etching may be employed to selectively remove materials from predefined areas on the substrate surface. For example, etched features such as vias, contacts, or trenches may be formed in the layers of the substrate.

One particular method of plasma processing uses an inductive source to generate the plasma. FIG. 1 illustrates a prior art inductive plasma processing reactor 100 that is used for plasma processing. A typical inductive plasma processing reactor includes a chamber 102 with an antenna or inductive coil 104 disposed above a dielectric window 106. Typically, antenna 104 is operatively coupled to a first RF power source 108. Furthermore, a gas port 110 is provided within chamber 102 that is arranged for releasing gaseous source materials, e.g., the etchant source gases, into the RF-induced plasma region between dielectric window 106 and a substrate 112. Substrate 112 is introduced into chamber 102 and disposed on a chuck 114, which generally acts as a bottom electrode and is operatively coupled to a second RF power source 116. Gases can then be exhausted through an exhaust port 122 at the bottom of chamber 102.

In order to create a plasma, a process gas is input into chamber 102 through gas port 110. Power is then supplied to inductive coil 104 using first RF power source 108. The supplied RF energy passes through dielectric window 106 and a large electric field is induced inside chamber 102. The electric field accelerates the small number of electrons present inside the chamber causing them to collide with the gas molecules of the process gas. These collisions result in ionization and initiation of a discharge or plasma 118. As is well known in the art, the neutral gas molecules of the process gas when subjected to these strong electric fields lose electrons, and leave behind positively charged ions. As a result, positively charged ions, negatively charged electrons and neutral gas molecules (and/or atoms) are contained inside the plasma 118.

Once the plasma has been formed, neutral gas molecules inside the plasma tend to be directed towards the surface of the substrate. By way of example, one of the mechanisms contributing to the presence of the neutral gas molecules at the substrate may be diffusion (i.e., the random movement of molecules inside the chamber). Thus, a layer of neutral species (e.g., neutral gas molecules) may typically be found along the surface of substrate 112. Correspondingly, when bottom electrode 114 is powered, ions tend to accelerate towards the substrate where they, in combination with neutral species, activate the etching reaction.

Plasma 118 predominantly stays in the upper region of the chamber (e.g., active region), however, portions of the plasma tend to fill the entire chamber. The plasma typically goes where it can be sustained, which is almost everywhere in the chamber. By way of example, magnetic fields may be employed to reduce plasma contact with the chamber wall 120. The plasma may contact areas on the chamber wall 120 and elsewhere if there are nodes in the magnetic field(s) confining the plasma. The plasma may also be in contact with regions where plasma is not required for meeting process objectives (e.g., regions 123 below the substrate 112 and gas exhaust port 122—non-active regions).

If the plasma reaches non-active regions of the chamber wall, etch, deposition and/or corrosion of the areas may ensue, which may lead to particle contamination inside the process chamber, i.e., by etching the area or flaking of deposited material. Accordingly, the chamber may have to be cleaned at various times during processing to prevent excessive build-ups of deposits (for example, resulting from polymer deposition on the chamber wall) and etched by-products. Cleaning disadvantageously lowers substrate throughput and typically adds costs due to loss of production. Moreover, the lifetime of the chamber parts is typically reduced.

Additionally, plasma interaction with the chamber wall can lead to recombination of the ions in the plasma with the wall and thus a reduction in the density of the plasma in the chamber during processing. In systems using a larger gap between the substrate and the RF source even greater plasma interaction and hence particle losses to the wall occur. To compensate for these increased losses, more power density is needed to ignite and maintain the plasma. Such increased power leads to higher electron temperatures in the plasma and, consequently, leads to potential damage of the substrate and the chamber wall as well.

Finally, in chambers using non-symmetric pumping of source gases, better control of a magnetic plasma confinement arrangement can help shape the plasma and compensate for such non-symmetric pumping.

In view of the foregoing, there are desired improved techniques and apparatuses for controlling a plasma inside a process chamber.

### SUMMARY OF THE INVENTION

The invention relates, in one embodiment, to a plasma processing apparatus for processing a substrate. The apparatus includes a substantially cylindrical process chamber within which a plasma is both ignited and sustained for processing. The chamber is defined at least in part by a wall. The apparatus further includes a plasma confinement arrangement. The plasma confinement arrangement includes a magnetic array disposed around the periphery of the process chamber. The magnetic array has a plurality of magnetic elements that are disposed radially and symmetrically about the axis of the process chamber. The plurality of magnetic elements is configured to produce a first magnetic field.

The magnetic field establishes a cusp pattern on the wall of the chamber. The cusp pattern on the wall of the chamber defines areas where a plasma might damage or create cleaning problems. The cusp pattern on the wall of the chamber is shifted to improve operation of the substrate processing system and to reduce the damage and/or cleaning problems caused by the plasma's interaction with the wall. Shifting of the cusp pattern can be accomplished by either moving the magnetic array or by moving the chamber wall. Movement of either component may be continuous (that is, spinning or translating one or more magnet elements or all or part of the wall) or incremental (that is, periodically shifting the position of one or more magnet elements or all or part of the wall).

The invention relates, in another embodiment, to a method for processing a substrate in a process chamber using a plasma enhanced process. The method includes producing a first magnetic field and resulting cusp pattern on the wall of the process chamber with a magnetic array. The method also includes creating the plasma inside the process chamber and confining the plasma within a volume defined at least by a portion of the process chamber and the resultant magnetic field. The method also includes moving the cusp pattern relative to the chamber wall to improve operation of the substrate processing system and to reduce the damage and/or cleaning problems caused by the plasma's interaction with the wall resulting from the cusp pattern.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 illustrates a prior art inductive plasma processing reactor that is used for plasma processing.

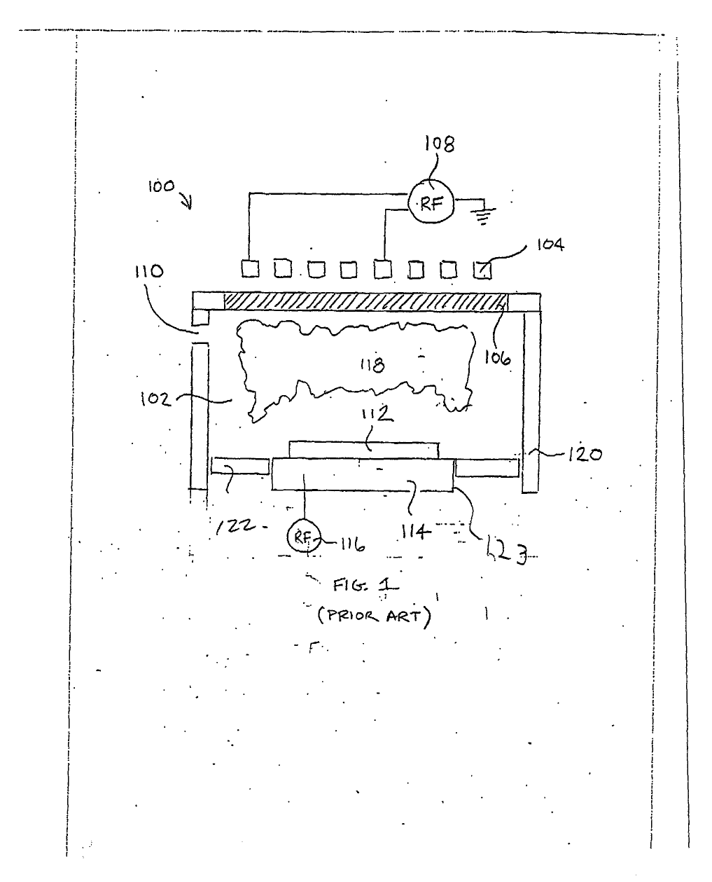

FIG. 2 shows an inductive plasma processing reactor utilizing a movable magnetic array, in accordance with one embodiment of the present invention.

FIG. 3A shows a partial cross sectional view of FIG. 2.

FIG. 3B shows the apparatus in FIG. 3A after the magnetic elements have been rotated.

FIG. 3C shows the apparatus in FIG. 3A after the magnetic elements have been rotated.

FIG. 3D illustrates another embodiment of the invention.

FIG. 4 illustrates another embodiment of the invention, which utilizes a separate inner chamber wall.

FIG. 5 is a schematic view of an electromagnet system that may be used in an embodiment of the invention.

FIG. 6 is an inductive plasma processing reactor utilized in another embodiment of the invention.

### DETAILED DESCRIPTION OF PREFERRED EMBODIMENTS

The present invention will now be described in detail with reference to a few preferred embodiments thereof and as illustrated in the accompanying drawings. In the following description, numerous specific details are set forth in order to provide a thorough understanding of the present invention. It will be obvious, however, to one skilled in the art, that the present invention may be practiced without some or all of these specific details. In other instances, well known process steps have not been described in detail to avoid obscuring the present invention.

In one embodiment, the present invention provides a plasma processing apparatus for processing a substrate. The plasma processing apparatus includes a substantially cylindrical process chamber, defined at least in part by a wall, within which a plasma is both ignited and sustained for processing the substrate.

Plasma processing takes place while a substrate is disposed on a chuck within the plasma processing chamber. A process gas, which is input into a plasma processing chamber, is energized and a plasma is created. The plasma tends to fill the entire process chamber, moving to active areas and to non-active areas. In the active area(s) in contact with the plasma, the ions and electrons of the plasma are accelerated towards the area, where they, in combination with the neutral reactants at the surface of the area, react with materials disposed on the surface. These interactions are often further controlled, enhanced or modified on the substrate by the application of RF power to the substrate support to process the substrate. In the non-active areas, where little or no control is provided to optimize the possible plasma enhanced reactions, adverse processing conditions can be produced (for example, reactions with unprotected regions of the chamber such as the areas of the wall where unwanted deposition of materials can take place). Ions, electrons and neutral species impinge both active and non-active areas in the reactor where they are in contact with the plasma. At the surface these fluxes interact with the surface causing etching, deposition or more typically a complicated balance of both depending on many parameters including the composition, temperature, energies of component fluxes to the surfaces. In many chemistries used for processing substrates, depositing neutral species has enhanced deposition rates on surfaces in contact with plasma bombardment. For the sake of argument and clarity we will consider these cases as typical for this invention, i.e., active areas in contact with the plasma tend to have plasma enhanced deposition while inactive areas with lower or no plasma exposure tend to have less deposition. This is not a limitation to the invention as there are other chemistries where the opposite is true and plasma exposure leads to surface erosion and less plasma leads to deposition.

In accordance with one aspect of the present invention, improved confinement of a plasma inside a plasma processing reactor is achieved by introducing a magnetic field inside the process chamber. The magnetic field and the resulting magnetic cusp pattern on the chamber wall are shifted to reduce, vary or average out the undesirable movement of the plasma to non-active areas of the process chamber that would otherwise result from a static cusp pattern. More specifically, either the magnetic array, elements of the magnetic array, the chamber, or portions of the chamber can be moved (continuously or incrementally) to control movement of the plasma into the non-active areas. The presence of the plasma in these non-active areas can reduce the efficiency of the processing apparatus, cause damage to the chamber and/or give rise to cleaning problems with the chamber wall. As a result, the processing apparatus functions more efficiently and frequent cleaning of the wall and damage thereto can be reduced.

While not wishing to be bound by theory, it is believed that a magnetic field can be configured to influence the direction of the charged particles, e.g., negatively charged electrons or ions and positively charged ions, in the plasma. Regions of the magnetic field can be arranged to act as a mirror field where the magnetic field lines are substantially parallel to a component of the line of travel of the charged particles and where the magnetic field line density and field strength increases and temporarily captures the charged particles in the plasma (spiraling around the field lines) and eventually redirects them in a direction away from the stronger magnetic field. In addition, if a charged particle tries to cross the magnetic field, cross field forces redirect the particle's motion and tend to turn the charged particle around or inhibit diffusion across the field. In this manner, the magnetic field inhibits movement of the plasma across an area defined by the magnetic field. Generally, cross field inhibition is more effective at containing plasma than a mirror field.

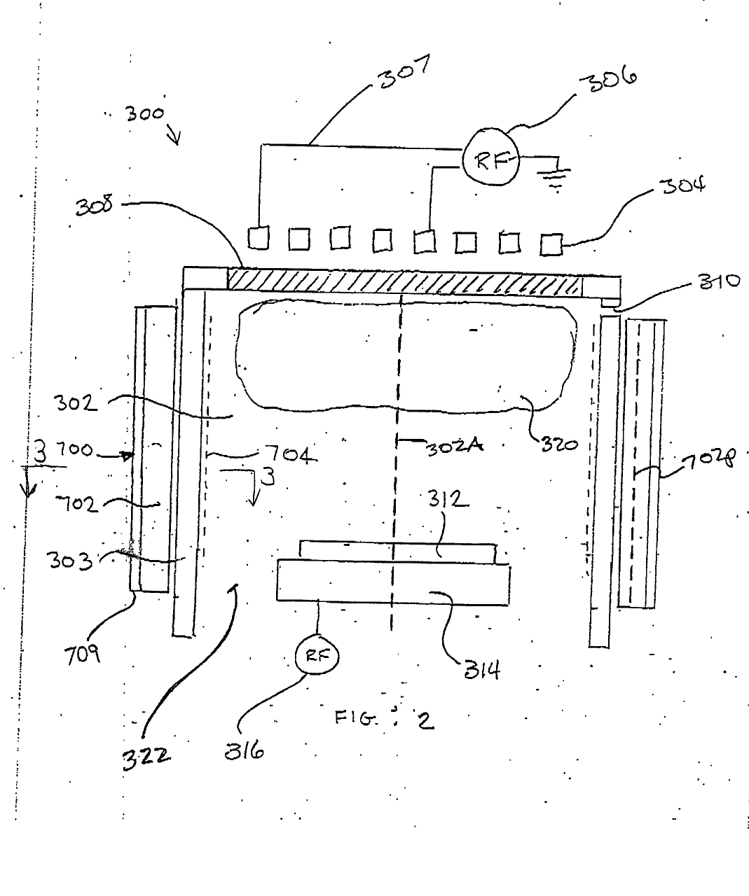

To facilitate discussion of this aspect of the present invention, FIG. 2 illustrates an exemplary plasma processing system 300 that uses one of the aforementioned movable magnetic arrays. The exemplary plasma processing system 300 is shown as an inductively coupled plasma reactor. However, it should be noted that the present invention may be practiced in any plasma reactor that is suitable for forming a plasma, such as a capacitively coupled or an ECR reactor.

Plasma processing system 300 includes a plasma processing chamber 302, a portion of which is defined by a chamber wall 303. For ease of manufacturing and simplicity of operation, process chamber 302 preferably is configured to be substantially cylindrical in shape with a substantially vertical chamber wall 303. However, it should be noted that the present invention is not limited to such and that various configurations of the process chamber may be used.

Outside chamber 302, there is disposed an antenna arrangement 304 (represented by a coil) that is coupled to a first RF power supply 306 via a matching network 307. First RF power supply 306 is configured to supply antenna arrangement 304 with RF energy having a frequency in the range of about 0.4 MHz to about 50 MHz. Furthermore, a coupling window 308 is disposed between antenna 304 and a substrate 312. Substrate 312 represents the work-piece to be processed, which may represent, for example, a semiconductor substrate to be etched, deposited, or otherwise processed or a glass panel to be processed into a flat panel display. By way of example, an antenna/coupling window arrangement that may be used in the exemplary plasma processing system is described in greater detail in a co-pending patent application Ser. No. 09/440,418 entitled, METHOD AND APPARATUS FOR PRODUCING UNIFORM PROCESS RATES, (Attorney Docket No.: LAM1P125/P0560), incorporated herein by reference.

A gas injector 310 is typically provided within chamber 302. Gas injector 310 is preferably disposed around the inner periphery of chamber 302 and is arranged for releasing gaseous source materials, e.g., the etchant source gases, into the RF-induced plasma region between coupling window 308 and substrate 312. Alternatively, the gaseous source materials also may be released from ports built into the walls of the chamber itself or through a shower head arranged in the coupling window. By way of example, a gas distribution system that may be used in the exemplary plasma processing system is described in greater detail in a co-pending patent application Ser. No. 09/470,236 entitled, PLASMA PROCESSING SYSTEM WITH DYNAMIC GAS DISTRIBUTION CONTROL; (Attorney Docket No.: LAM1P123/P0557), incorporated herein by reference.

For the most part, substrate 312 is introduced into chamber 302 and disposed on a chuck 314, which is configured to hold the substrate during processing in the chamber 302. Chuck 314 may represent, for example, an ESC (electrostatic) chuck, which secures substrate 312 to the chuck's surface by electrostatic force. Typically, chuck 314 acts as a bottom electrode and is preferably biased by a second RF power source 316. Second RF power source 316 is configured to supply RF energy having a frequency range of about 0.4 MHz to about 50 MHz.

Additionally, chuck 314 is preferably arranged to be substantially cylindrical in shape and axially aligned with process chamber 302 such that the process chamber and the chuck are cylindrically symmetric. However, it should be noted that this is not a limitation and that chuck placement may vary according to the specific design of each plasma processing system. Chuck 314 may also be configured to move between a first position (not shown) for loading and unloading substrate 312 and a second position (not shown) for processing the substrate. An exhaust port 322 is disposed between chamber walls 303 and chuck 314 and is coupled to a turbomolecular pump (not shown), typically located outside of chamber 302. As is well known to those skilled in the art, the turbomolecular pump maintains the appropriate pressure inside chamber 302.

Furthermore, in the case of semiconductor processing, such as etch processes, a number of parameters within the processing chamber need to be tightly controlled to maintain high tolerance results. The temperature of the processing chamber is one such parameter. Since the etch tolerance (and resulting semiconductor-based device performance) can be highly sensitive to temperature fluctuations of components in the system, accurate control is required. An example of a temperature management system that may be used in the exemplary plasma processing system to achieve temperature control is described in greater detail in a co-pending patent application Ser. No. 09/439,675 entitled, TEMPERATURE CONTROL SYSTEM FOR PLASMA PROCESSING APPARATUS; (Attorney Docket No.: LAM1P124/P0558), incorporated herein by reference.

Additionally, another important consideration in achieving tight control over the plasma process is the material utilized for the plasma processing chamber, e.g., the interior surfaces such as the chamber wall. Yet another important consideration is the gas chemistries used to process the substrates. An example of both materials and gas chemistries that may be used in the exemplary plasma processing system are described in greater detail in a co-pending patent application Ser. No. 09/440,794 entitled, MATERIALS AND GAS CHEMISTRIES FOR PLASMA PROCESSING SYSTEMS, (Attorney Docket No.: LAM1P128/P0561-1), incorporated herein by reference.

In order to create a plasma, a process gas is input into chamber 302 through gas injector 310. Power is then supplied to antenna 304 using first RF power source 306, and a large electric field is produced inside chamber 302. The electric field accelerates the small number of electrons present inside the chamber causing them to collide with the gas molecules of the process gas. These collisions result in ionization and initiation of a discharge or plasma 320. As is well known in the art, the neutral gas molecules of the process gas, when subjected to these strong electric fields, lose electrons and leave behind positively charged ions. As a result, positively charged ions, negatively charged electrons and neutral gas molecules are contained inside plasma 320.

Once the plasma has been formed, neutral gas molecules inside the plasma tend to be directed towards the surface of the substrate. By way of example, one of the mechanisms contributing to the presence of neutral gas molecules at the substrate may be diffusion (i.e., the random movement of molecules inside the chamber). Thus, a layer of neutral species (e.g., neutral gas molecules) may typically be found along the surface of substrate 312. Correspondingly, when bottom electrode 314 is powered, ions tend to accelerate towards the substrate where they, in combination with neutral species, activate substrate processing, i.e., etching, deposition and/or the like.

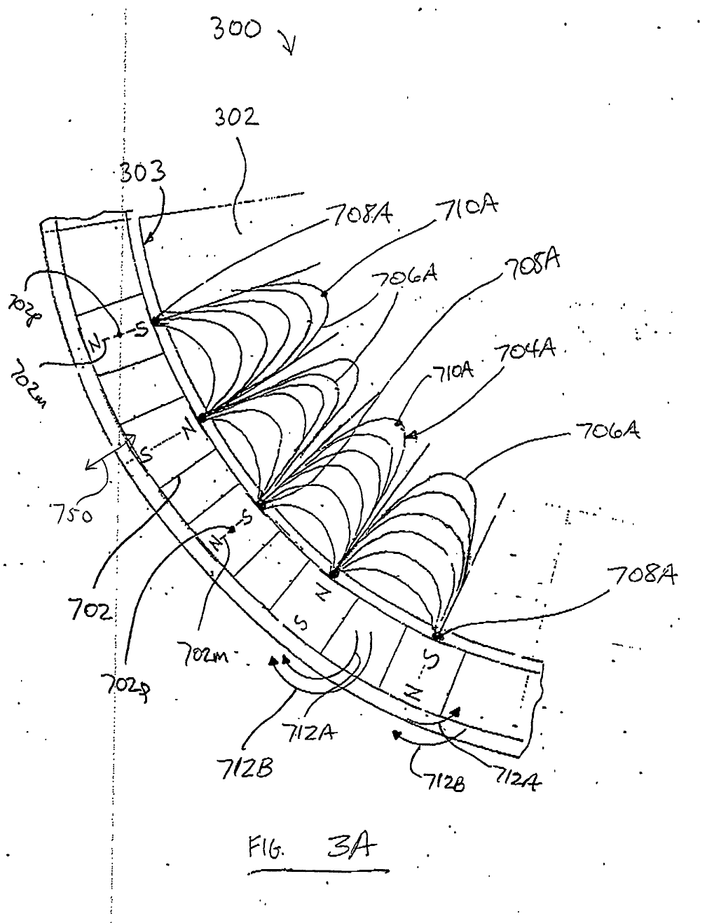

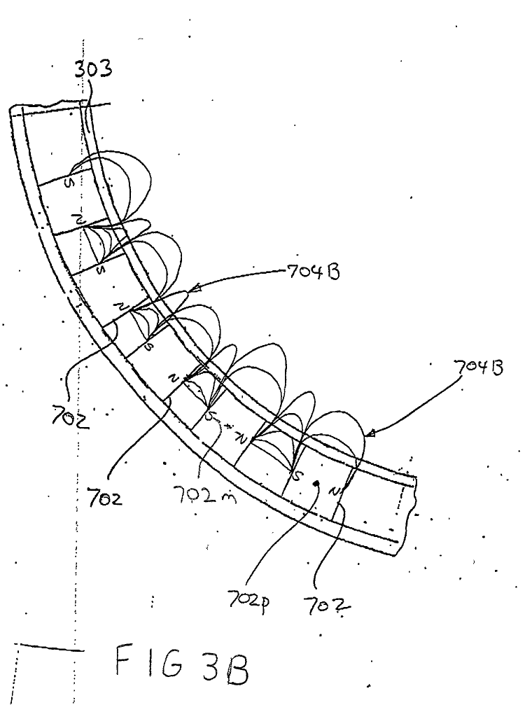

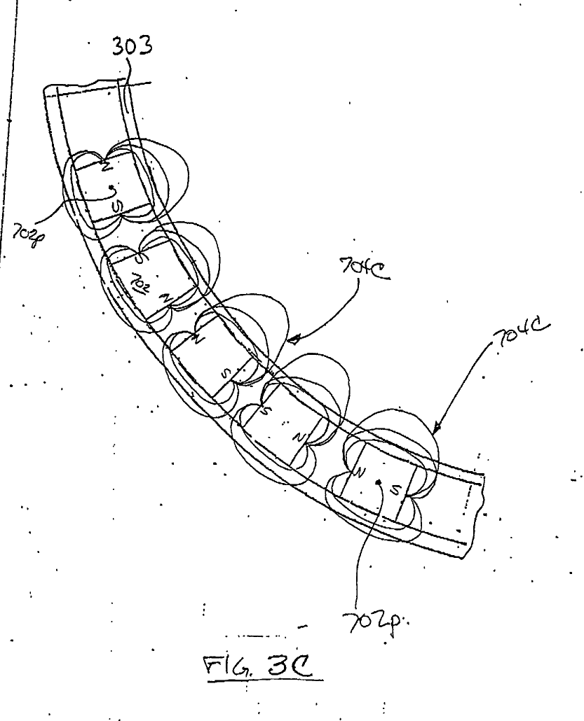

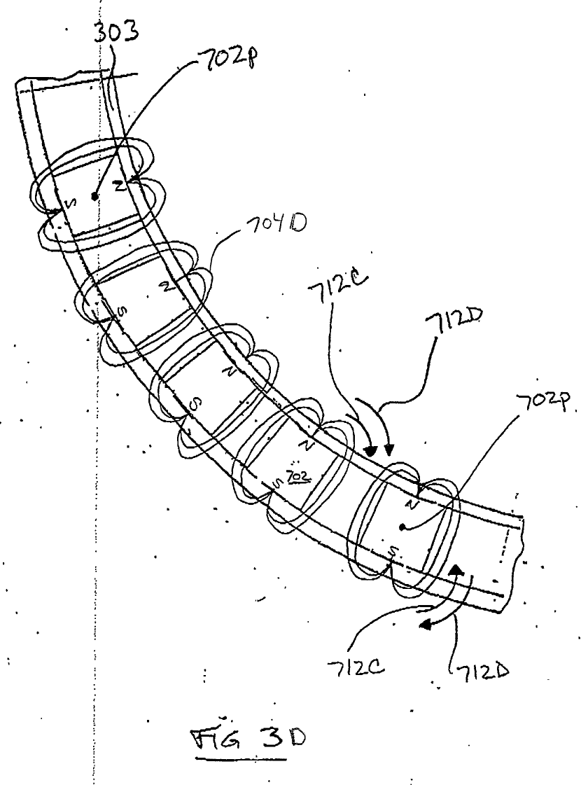

FIG. 2 shows plasma processing system 300 with a magnetic array 700 in accordance with the present invention. FIG. 3A is a partial cross sectional view of FIG. 2 along cut lines 3-3 in an embodiment of the invention. Magnetic array 700 includes a plurality of vertical magnetic elements 702, which span substantially from the top of process chamber 302 to the bottom of process chamber 302. Magnetic array 700 includes a plurality of magnetic elements 702 that are disposed radially and symmetrically about the vertical chamber axis 302A of process chamber 302. In the preferred embodiment, each magnetic element 702 is generally rectangular in cross-section and is an elongate bar having a number of longitudinal physical axes. An important axis is shown in the figure as 702p. Each magnetic element has a magnetic orientation defined by a north pole (N) and a south pole (S) connected by a magnetic axis 702m. In the preferred embodiment the magnetic axis 702m is along the longer axis of the rectangular cross section. In the preferred embodiment, the physical axis along the elongate bar 702p and magnetic axis 702m are perpendicular in each magnetic element 702. More preferably, magnetic elements 702 are axially oriented about the periphery of the process chamber such that either of their poles (e.g., N or S) point toward the chamber axis 302A of process chamber 302, as shown in FIG. 3A, i.e., the magnetic axes 702m are substantially in the chamber radial direction. More preferably the physical axis 702p of each magnetic element 702 is substantially parallel to the chamber axis 302A of the process chamber 302. Cusps 708A form adjacent magnetic elements where field lines group together, i.e., the north or south ends of the magnet elements. Further still, magnetic elements 702 are spatially offset along the periphery of the process chamber such that a spacing is provided between each of the magnetic elements 702 approximately equal to the length of the rectangular cross section. It should be understood that the size of the spacing may vary according to the specific design of each plasma processing system.

The total number of first magnetic elements 702 is preferably equal to 32 for a chamber large enough to process 300 mm substrates. However, the actual number of magnetic elements per chamber may vary according to the specific design of each plasma processing system. In general, the number of magnetic elements should be sufficiently high to ensure that there is a strong enough plasma confining magnetic field to effectively confine the plasma. Having too few magnetic elements may create low points in the plasma confining magnetic field, which as a result may allow the plasma further access to undesired areas. However, too many magnetic elements may degrade the density enhancement because the losses are typically highest at the cusp along the field lines.

Preferably but not necessarily, the magnetic elements 702 are configured to be permanent magnets that are each about the same size and produce about the same magnetic flux. However, having the same size and magnetic flux is not a limitation, and in some configurations it may be desirable to have magnetic elements with different magnetic fluxes and sizes. By way of example, a magnetic flux of about 50 to about 1500 Gauss may be suitable for generating a plasma confining magnetic field that is sufficiently strong to inhibit the movement of the plasma. Some things that may affect the amount of flux and size of magnets needed are the gas chemistries, power, plasma density, etc. Preferably, the permanent magnets are formed from a sufficiently powerful permanent magnet material, for example, one formed from the NdFeB (Neodymium Iron Boron) or SmCo (Samarium Cobalt) families of magnetic material. In some small chambers, AlNiCo (aluminum, nickel, cobalt and iron) or ceramics may also work well.

Again, for the most part, the strength of the magnetic flux of the magnetic elements 702 has to be high in order to have significant field strength away from the magnets. If too low of a magnetic flux is chosen, regions of low field in the plasma confining magnetic field will be larger, and therefore the plasma confining magnetic field may not be as effective at inhibiting the plasma diffusion. Thus, it is preferable to maximize the field. Preferably, the plasma confinement magnetic field has a magnetic field strength effective to prevent the plasma from passing through the plasma confinement magnetic field. More specifically, the plasma confinement magnetic field should have a magnetic flux in the range of about 15 to about 1500 Gauss, preferably from about 50 to about 1250 Gauss, and more preferably from about 750 to about 1000 Gauss.

Furthermore, the distance between the magnetic elements and the process chamber should be minimized in order to make better use of the magnetic energy produced by the magnetic elements. That is, the closer the magnetic elements are to the process chamber, the greater the intensity of the magnetic field produced within the process chamber. If the distance is large, a larger magnet may be needed to get the desired magnetic field. Preferably, the distance is between about 1/16″ and about 1 inch. It should be understood that the distance may vary according to the specific material used between the magnetic elements and the process chamber. Clearance may also be needed to permit movement of the magnetic elements.

With respect to the magnetic fields employed, it is generally preferred to have zero or near zero magnetic fields proximate to the substrate. A magnetic flux near the surface of the substrate tends to adversely affect process uniformity. Therefore, the magnetic fields produced by plasma confinement arrangement are preferably configured to produce substantially zero magnetic fields above the substrate. Also, one or more additional magnetic confinement arrays may be used adjacent the exhaust port 322 to further enhance confinement of the plasma within chamber 302. An example of an exhaust port confinement array arrangement is described in greater detail in the co-pending patent application Ser. No. 09/439,759 entitled, METHOD AND APPARATUS FOR CONTROLLING THE VOLUME OF A PLASMA, (Attorney Docket No.: LAM1P129/P0561), incorporated herein by reference.

In accordance with another aspect of the present invention, a plurality of flux plates can be provided to control any stray magnetic fields produced by the magnetic elements of the plasma confinement arrangement. The flux plates are configured to short circuit the magnetic field in areas that a magnetic field is not desired, for example, the magnetic field that typically bulges out on the non-used side of the magnetic elements. Further, the flux plates redirect some of the magnetic field and therefore a more intense magnetic field may be directed in the desired area. Preferably, the flux plates minimize the strength of the magnetic field in the region of the substrate, and as a result the magnetic elements can be placed closer to the substrate. Accordingly, a zero or near zero magnetic field proximate to the surface of the substrate may be achieved.

Note that although the preferred embodiment contemplates that the magnetic field produced be sufficiently strong to confine the plasma without having to introduce a plasma screen into the chamber, it is possible to employ the present invention along with a plasma screen to increase plasma confinement. By way of example, the magnetic field may be used as a first means for confining the plasma and the plasma screen, typically a perforated grid in pump port 322 may be used as a second means for confining the plasma.

Preferably, the chamber wall 303 is formed from a non-magnetic material that is substantially resistant to a plasma environment. By way of example, wall 303 may be formed from SiC, SiN, Quartz, Anodized Al, Boron Nitride, Boron Carbide and the like.

Magnetic array 700 and magnetic elements 702 are configured to force a substantial number of the plasma density gradients to concentrate near the chamber walls away from the substrate by producing a chamber wall magnetic field 704 proximate to chamber wall 303. In this manner, uniformity is further enhanced as the plasma density gradient change across substrate 312 is minimized. Process uniformity is improved to a much greater degree in the improved plasma processing system than is possible in many plasma processing systems. An example of a magnetic array arrangement close to a coupling window and antenna is described in greater detail in the co-pending patent application Ser. No. 09/439,661 entitled, IMPROVED PLASMA PROCESSING SYSTEMS AND METHODS THEREFOR (Attorney Docket No.: LAM1P0122/P0527), incorporated herein by reference.

As seen in FIG. 3A the convergence and resulting concentration of the field lines 706A defining field 704A creates a number of nodes or cusps 708A forming a cusp pattern about the chamber wall 303.

A magnetic field generally inhibits ion penetration of charged particles through the part 710A of the field 704 substantially perpendicular to the line of travel of the plasma travelling to the wall 303 due to the tendency of a magnetic field to inhibit cross field diffusion of charged particles. Inhibition of cross field diffusion helps to contain plasma at such points 710A traveling towards the chamber wall 303. At points of the magnetic field that are substantially parallel to the line of travel of plasma travelling to the wall 303 are cusps 708A, where the magnetic field lines become denser. This increase in field line density causes a magnetic mirror effect, which also reflects the plasma, but which is not as effective in containing plasma cross field inhibition. The magnetic fields can increase the effective mean free path of electrons and ions to improve ignition of the plasma and improve efficiency of the power consumption. Lower power density is needed for ignition of the plasma. Although the magnetic field 704A generated by the magnetic array 700 is illustrated as covering a specific area and depth into the chamber 302, it should be understood that placement of the plasma confining field may vary. For example, the strength of the magnetic field can be selected by one of ordinary skill in the art to meet other performance criteria relating to processing of a substrate.

In one embodiment of the present invention, the magnetic elements 702 are manipulated on an element-by-element basis to change the magnetic field generated by array 700. As will be seen below, there are alternative methods for shifting the magnetic field generated in the chamber 302.

As discussed above, the magnetic axes 702m of elements 702 extend radially relative to the chamber 302. As seen in FIG. 3A, the magnetic elements in the preferred embodiment also are in an alternating polar orientation. That is, the inwardly directed pole of each consecutive magnetic element 702 alternates N-S-N-S-N-S-N-S to create the magnetic field 704A.

The magnetic elements 702 may be rotated physically by any suitable device 709, including manual rotation or rotation by mechanical means, such as a belt or chain system (with appropriate accommodation being made for the presence of the magnetic fields of the magnetic elements 702). As noted below, the use of electromagnets can change the way the magnetic field is shifted, as will be apparent to one of ordinary skill in the art.

When the individual magnetic elements are rotated, the magnetic field 704 shifts and changes. Depending on the original orientation of the magnetic elements and the direction(s) in which they are rotated, different fluctuations in the magnetic field 704 can be induced. Consequently, different shifts in the cusp pattern can be achieved. In FIGS. 3A-3C, the effects of rotating the magnetic elements 702 about their physical axes 702p in various rotation patterns are shown.

In a first embodiment, beginning with the configuration of FIG. 3A, the magnetic elements 702 are in an alternating radial magnetic axes orientation around the circumference of the chamber. As indicated by arrows 712A, every other magnetic element 702 is rotated about its physical axis 702p in a clockwise manner. The remaining magnetic elements 702 are rotated in a counterclockwise manner. FIG. 3B shows the altered magnetic field 704B after the magnetic elements 702 have been rotated 90°. In rotating the magnetic elements from the position in FIG. 3A to the position in FIG. 3B, the cusps of the magnetic field shift from being near the center of the magnetic elements 702 to positions near the sides of the magnetic elements 702. This causes most of the plasma deposition on the chamber wall 303 to shift from locations near the center of the magnetic elements 702 to locations near the sides of the magnetic elements 702. After another 90° of rotation, the magnetic elements are again in positions similar to the positions shown in FIG. 3A, wherein the magnetic elements 702 reestablish the magnetic field 704A in a position that is effectively equivalent to its starting configuration, although each magnetic element 702 has rotated 180°. The cusps of the magnetic field shift from locations near the sides of the magnetic elements 702 to the center of the magnetic elements 702, which causes most of the plasma deposition on the chamber wall 303 to shift from locations of the chamber wall 303 that are near the sides of the magnetic element 702 to locations near the center of the magnetic elements 702. The magnetic elements 702 continue to rotate until they are back in their original position shown in FIG. 3A, completing a cycle. The magnetic elements 702 may continue through another cycle until the plasma is extinguished.

In a second embodiment, again beginning with the configuration of FIG. 3A, the magnetic elements 702 again are initially in an alternating radial polar orientation. As indicated by arrows 712B, however, every magnetic element 702 is rotated about its physical axis 702p in a clockwise manner. FIG. 3C shows the altered magnetic field 704C after the magnetic elements 702 have been rotated 90°. Adjoining magnetic elements 702 have their N and S poles facing one another at this point with magnetic axes 702m azimuthally oriented. In rotating the magnetic elements from the position in FIG. 3A to the position in FIG. 3C, the cusps of the magnetic field shift from being near the center of the magnetic elements 702 to positions between adjacent magnetic elements 702. This causes most of the plasma deposition on the chamber wall 303 to shift from locations near the center of the magnetic elements 702 to locations between adjacent magnetic elements 702. After another 90° of rotation, the magnetic elements 702 are again in positions similar to the positions shown in FIG. 3A, wherein the magnetic elements 702 reestablish the magnetic field 704A in a position that is effectively equivalent to its starting configuration, although each magnetic element 702 has rotated 180°. The cusps of the magnetic field shift from locations between adjacent magnetic elements 702 to the center of the magnetic elements 702, which causes most of the plasma deposition on the chamber wall 303 to shift to locations of the chamber wall 303 between adjacent magnetic element 702 to locations near the center of the magnetic elements 702. The magnetic elements 702 continue to rotate until they are back in their original position shown in FIG. 3A, completing a cycle. The magnetic elements 702 may continue through another or many cycles until the plasma is extinguished.

A third embodiment of the present invention starts with the magnetic elements 702 as shown in FIG. 3D, wherein the magnetic elements 702 are in a consistent radial polar orientation establishing a magnetic field 704D. As shown in FIG. 3D, a consistent polar alignment (N-N-N-N-N-N or S-S-S-S-S-S) also can be used to generate a different initial static field 704D. As indicated by arrows 712C, every other magnetic element 702 is rotated in a clockwise manner. The remaining magnetic elements 702 are rotated in a counterclockwise manner. FIG. 3C shows the altered magnetic field 704C after the magnetic elements 702 have been rotated 90°. In rotating the magnetic elements from the position in FIG. 3D to the position in FIG. 3C, the cusps of the magnetic field shift from being near the center of the magnetic elements 702 and between the magnetic elements 702 to positions only between adjacent magnetic elements 702. This causes most of the plasma deposition on the chamber wall 303 to shift from locations near the center of the magnetic elements 702 and between adjacent magnetic elements 702 to locations only between adjacent magnetic elements 702. After another 90° of rotation, the magnetic elements 702 are again in positions similar to the positions shown in FIG. 3D, wherein the magnetic elements 702 reestablish the magnetic field 704B that is effectively equivalent to its starting configuration, although each magnetic element 702 has rotated 180°. The cusps of the magnetic field shift from locations only between adjacent magnetic elements 702 to the center of the magnetic elements 702 and between adjacent magnetic elements 702, which causes most of the plasma deposition on the chamber wall 303 to shift to locations of the chamber wall 303 from only between adjacent magnetic element 702 to locations near the center of the magnetic elements 702 and between adjacent magnetic elements 702. The magnetic elements 702 continue to rotate until they are back in their original position shown in FIG. 3D, completing a cycle. The magnetic elements 702 may continue through another cycle until the plasma is extinguished.

In a fourth embodiment starting with the configuration shown in FIG. 3D, the magnetic elements 702 again are in a consistent radial polar orientation. As indicated by arrows 712D, however, every magnetic element 702 is rotated about its physical axis 702p in a clockwise manner. FIG. 3B shows the altered magnetic field 704D after the magnetic elements 702 have been rotated 90°. Adjoining magnetic elements 702 have their N and S poles facing one another at this point. In rotating the magnetic elements from the position in FIG. 3D to the position in FIG. 3B, the cusps of the magnetic field shift from being near the center of the magnetic elements 702 and between adjacent magnetic elements 702 to positions near the sides of the magnetic elements 702. This causes most of the plasma deposition on the chamber wall 303 to shift from locations near the center of and between the magnetic elements 702 to locations near the sides of the magnetic elements 702. After another 90° of rotation, the magnetic elements are again in positions similar to the positions shown in FIG. 3D, wherein the magnetic elements 702 reestablish the magnetic field 704B in a position that is effectively equivalent to its starting configuration, although each magnetic element 702 has rotated 180°. The cusps of the magnetic field shift from locations near the sides of the magnetic elements 702 to the center of the magnetic elements 702 and between adjacent magnetic elements 702, which causes most of the plasma deposition on the chamber wall 303 to shift from locations of the chamber wall 303 that are near the sides of the magnetic element 702 to locations near the center of and between the magnetic elements 702. The magnetic elements 702 continue to rotate until they are back in their original position shown in FIG. 3D, completing a cycle. The magnetic elements 702 continue through another cycle until the plasma is extinguished.

In a preferred embodiment of a process that may be used with one of the above embodiments the variations are periodical during a single plasma processing step so that there is more than one cycle in the shift in the cusp pattern of the magnetic field during a single plasma processing step. More preferably, in this embodiment, the magnetic field cusp pattern goes through more than ten cycles during a single plasma processing step. In another preferred embodiment of a process that may be used with one of the above embodiments the shift in the cusp pattern goes through only a single cycle during a single plasma processing step. In another preferred embodiment of a process that may be used with the above embodiments, the shift in the cusp pattern of the magnetic field goes through only a portion of a cycle during a process step. In these embodiments of different processes, the shift in the cusp pattern may be continuous or incremental so that the cusp pattern is static for a time. The exact choice of variation depends on the process step. For instance, as mentioned above, the depth or composition of the deposition along the wall may vary as the magnetic field varies yet in a subsequent clean step it would be beneficial to change the magnetic field to enhance cleaning of the deposition pattern resulting from the first configuration.

Other orientations of the magnetic elements, other than the configurations shown in FIGS. 3A-D, may be used in the practice of the invention, as long as the resulting magnetic field has an azimuthally symmetric radial gradient in that the N-S magnetic axes 702m for all magnetic elements create a plurality of cusp patterns on the chamber wall 303 resulting in a high magnetic field near the chamber wall and a low magnetic field at the substrate. As shown in the preferred embodiment there is a weak field above the substrate and a strong field near the wall with primarily radial gradients in field strength at the substrate. In addition the primary gradients in the field are radial throughout the chamber even above and below the substrate.

With proper design of the magnetic field the resulting plasma and neutral chemistry can be made symmetric enough above the substrate for symmetric process results. However, increasing processing requirements may someday be sensitive enough that subtle effects due to the periodicity of the static magnetic field will be visible in substrate processing results. Therefore with changes to the cusp pattern during rotation, it will be further appreciated that the magnetic field 704 will be more homogeneous on average in its containment function since charged particles in the plasma will not be permitted to concentrate as readily as a result of the time varying field line structure of the magnetic field. Each portion of the wall in contact with the alternating cusps will on average have the same flux of ion, electrons and neutrals and hence produce even more uniform substrate results. Similarly any erosion or change in wall characteristics will be smoothed out over the whole surface.

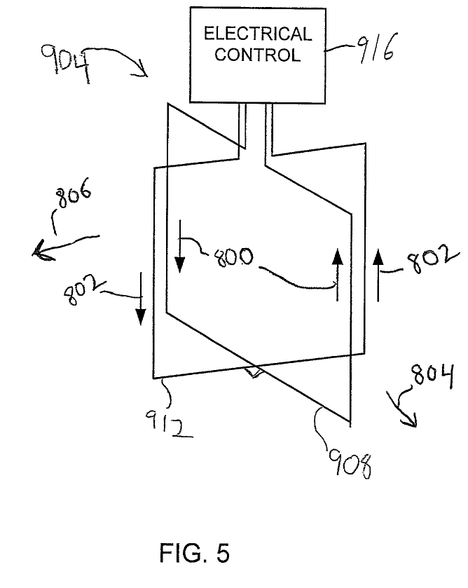

FIG. 5 illustrates an electromagnet system 904, which may be used as the magnetic elements 702 in FIGS. 2-3D. The electromagnetic system 904 comprises a first electromagnet 908, a second electromagnet 912, and an electrical control 916. The first and second electromagnets 908, 912 each comprise at least one current loop, with only one current loop being shown for clarity. In operation, the electrical control 916 provides a first current 800 in the first electromagnet 908 to create a first magnetic field 806 and a second current 802 in the second electromagnet 912 to create a second magnetic field 804. By having the electrical control 916 change the magnitudes and direction of the first and second currents 800, 802 over time, the sum of the resulting first and second magnetic fields 806, 804 results in the same rotating magnetic field provided by the magnetic elements 702 in FIGS. 2-3D. This embodiment shows that it is possible to control movement of the magnetic field by using magnetic elements 702, which are electromagnets. Electromagnets offer the advantage of controlling the amount of magnetic flux, so that better process control may be achieved. However, electromagnets tend to further complicate the manufacturability of the system. In this embodiment of the invention, the electrical current supplied to the magnetic array 700 can control the strength and orientation of the magnetic field. Of course, electromagnetic magnetic elements 702 also could be physically manipulated in just the same way as permanent magnets to achieve the desired modulation in the magnetic field.

In another embodiment of the present invention, the individual magnetic elements 702 maintain their physical and magnetic orientations relative to one another, but are shifted instead as a unit relative to the chamber 302 and wall 303. Again the device 709 used to move the magnetic array 700 can be any suitable manual or mechanical apparatus. The starting positions of the magnetic elements 702 can be the same as shown in FIGS. 3A through 3D (more preferably 3A or 3B), above, either an alternating radial polar orientation or a consistent radial polar orientation. Rather than rotate each magnetic element 702 separately, the magnetic array 700 is rotated about the axis 302A of chamber 302. This type of rotation will cause the cusp pattern imposed on wall 303 by the magnetic array 700 to likewise rotate about wall 303. The field lines of the magnetic field (704A or 704B) do not change relative to one another, as was the case when the magnetic elements 702 were rotated individually. Instead, the magnetic field moves in its entirety. A full rotation about axis 302A of chamber 302 can be performed or a fraction of a rotation with preferable fraction equal to the magnetic field periodicity.

Again, rotation of the entire magnetic array 700 as a unit provides a more homogeneous magnetic field in the chamber 302 for processing than would be achievable with a static magnetic array. No single area or location on the chamber wall 303 will be affected substantially more or substantially less than elsewhere. Moreover, the reflective and diffusion inhibiting properties of the magnetic field will be applied more equally to the charged particles within the plasma. In addition to reducing damage and cleaning problems with the chamber wall 303, the enhanced confinement of the plasma within chamber 302 (reducing losses to the wall) permits use of a lower power level to sustain the plasma during processing or elongation of the longitudinal dimension of the chamber 302 to provide a greater mean free path and better substrate strike at the same power level than was used for earlier processing systems.

In another embodiment of the invention, the magnetic elements 702 may be individually moved radially as indicated by arrow 750 in FIG. 3A. The magnetic elements 702 are moved symmetrically in a radial direction, which weakens and then strengthens the magnetic bucket. This change in the magnetic field creates a more homogeneous magnetic field and causes a more homogeneous deposition on the chamber wall. In addition, the radial motion of the magnets increases or decreases the efficiency of the magnetic confinement and thus changes the radial diffusion profile of the plasma.

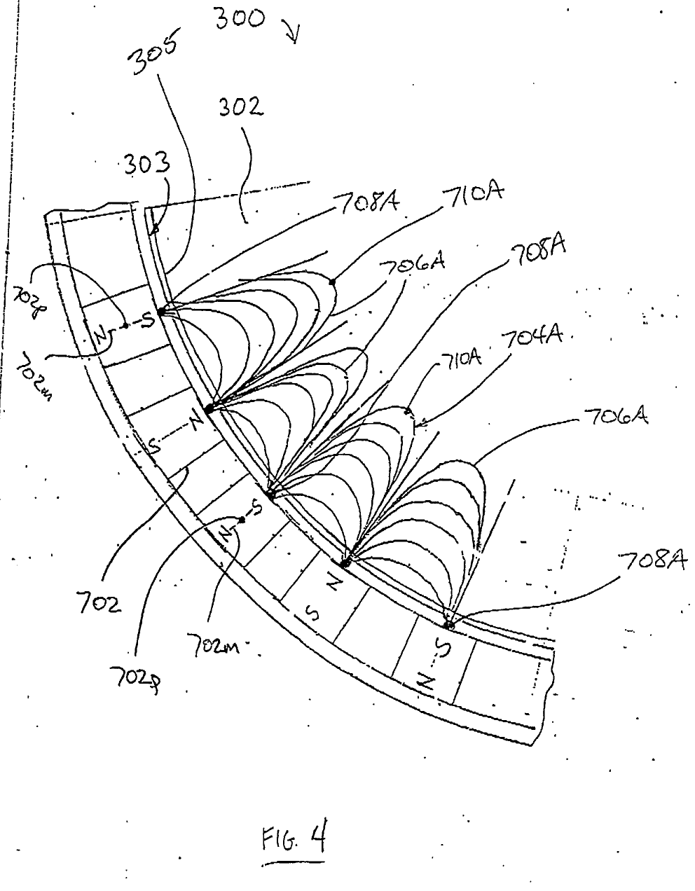

In another embodiment, the magnetic array 700 can be held in a static position and all or a part of the chamber wall 303 can be shifted or rotated. In light of the complications, which would arise from attempting to rotate the entire chamber 303, an inner chamber wall 305 can be used. As seen in FIG. 4, inner chamber wall 305, rather than the outer chamber wall 303, will be the processing chamber component that the plasma contacts. Again, suitable means 309 are used to move the inner chamber wall 305 as needed. Moreover, a suitable (perhaps disposable) material forming a liner can be selected to act as the inner chamber wall 305.

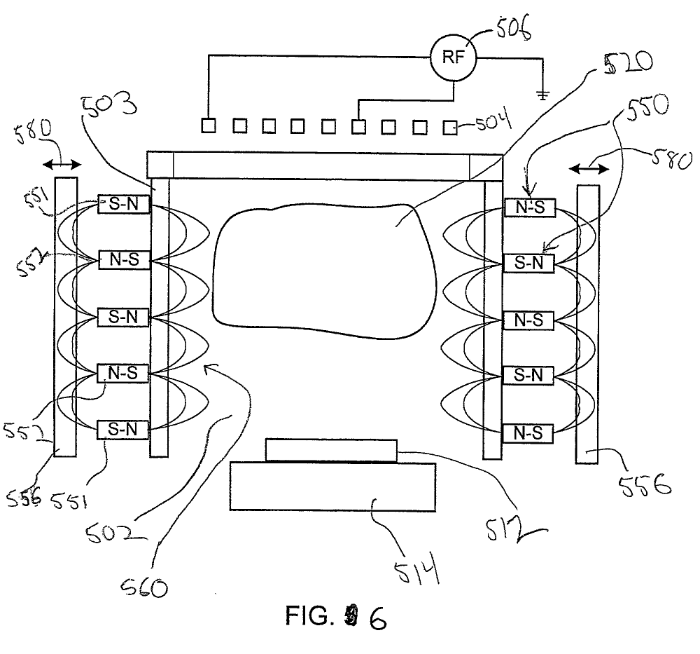

FIG. 6 illustrates another embodiment of the invention. In FIG. 6 a chamber wall 503 of a process chamber 502 is surrounded by a plurality of magnet elements 550 in the shape of rings, wherein each ring shaped magnetic element 550 surrounds the periphery of the chamber wall 503. The ring shape magnetic elements 550 alternate so that some ring shape magnetic elements 551 have the magnetic north pole on the interior of the ring and the magnetic south pole on the outer part of the ring and alternate ring shape magnetic elements 552 have the magnetic north pole on the outer part of the ring and the magnetic south pole on the interior of the ring. Flux plates 556 form sections placed around the periphery of the ring shape magnetic elements 550. A substrate 512 is placed on a chuck 514. An RF power supply 506 supplies power to an antenna arrangement 504, which energizes an etchant gas to form a plasma 520. The magnetic elements 550 create a magnetic field 560 with a cusp pattern as shown. The cusp pattern in this embodiment is not primarily parallel to the axis of the chamber, but instead is substantially perpendicular to the axis of the chamber. In another embodiment of the invention, the poles of the ring shape elements may be alternating pointing in nearly axial directions (analogous to FIG. 3C), non-alternating pointing in nearly axial directions (analogous to FIG. 3B) or non-alternating pointing in the radial direction (analogous to FIG. 3D). In this embodiment of the invention, the flux plates 556 are radially translated as shown by arrows 580. The movement of the flux plates 556 causes the magnetic field 560 to shift. In this embodiment, the flux plates 556 may be moved close to the magnetic elements 550 during a plasma processing step to increase the magnetic field near the chamber wall 503 during plasma processing and then moved further from the magnetic elements 550 to decrease the magnetic field near the chamber wall 503 during a cleaning step.

All of the above-mentioned embodiments disclose a method and apparatus for using a plurality of magnets to produce a plurality of cusp patterns on a chamber wall and changing a plurality of cusp patterns with respect to the chamber wall. This pattern returns the magnetic cusp pattern to an original position over a period of time. This changing pattern may be produced by moving the plurality of magnets individually or as a group, by changing the current in electromagnets, moving flux plates or by moving the chamber wall with respect to the magnets. The moving chamber wall can be the moving of the whole wall of the chamber or an inner chamber wall, which forms a liner for an outer chamber wall.

As can be seen from the foregoing, the present invention offers numerous advantages over the prior art. By way of example, the invention provides more homogeneous effects of the magnetic field that is configured for confining a plasma. Consequently, the magnetic field is more effective in substantially preventing the plasma from moving to non-active areas of the process chamber. More importantly, the plasma can be better controlled to a specific volume and a specific location inside the process chamber. In this manner, a more uniform plasma density is obtained, which as a result tends to produce more uniform processing, i.e., the center and the edge of the substrate having substantially the same etch rate during etching. In addition, the movement of the magnetic field changes the location of the cusps with respect to the chamber wall. This allows the plasma that escapes through the cusps to be spread along the chamber wall, allowing for a more uniform cleaning of the chamber wall. In addition, parts of the chamber wall away from the cusp region would receive a coating of neutral particles. By shifting the magnetic field, a coating of charged particles would be added to the coating of neutral particles, which would allow easier cleaning of the chamber wall. Also the uniformity of the plasma can be adjusted for different process conditions using different movements of the magnets. The mean free path of ions and electrons within the chamber can also be adjusted through modification of the magnetic field. This can lead to a modification of the plasma chemistry and can be used as a parameter to impact process performance either on cleaning the chamber walls or processing the substrate.

While this invention has been described in terms of several preferred embodiments, there are alterations, permutations, and equivalents which fall within the scope of this invention. It should also be noted that there are many alternative ways of implementing the methods and apparatuses of the present invention. It is therefore intended that the following appended claims be interpreted as including all such alterations, permutations, and equivalents as fall within the true spirit and scope of the present invention.

What is claimed is:

1. A plasma processing apparatus for processing a substrate, comprising:
a process chamber, defined at least in part by a wall, within which a plasma is ignited and sustained for said processing;
a magnetic array having a plurality of magnetic elements that are disposed around the periphery of said process chamber, said plurality of magnetic elements being configured to produce a magnetic field establishing a plurality of cusp patterns on said wall; and
a device for changing said cusp pattern with respect to said wall connected between the plurality of magnetic elements and the process chamber.

2. The apparatus, as recited in claim 1, further comprising a chuck within the process chamber for supporting the substrate within the process chamber.

3. The apparatus, as recited in claim 2, wherein the magnetic field has an azimuthally symmetric radial gradient.

4. The apparatus, as recited in claim 3, wherein said magnetic elements are permanent magnets.

5. The apparatus, as recited in claim 3, wherein said magnetic elements are electromagnets.

6. The apparatus, as recited in claim 3, wherein said device for changing said cusp pattern continuously changes the cusp pattern on said wall.

7. The apparatus, as recited in claim 3, wherein said device for changing said cusp pattern incrementally changes the cusp pattern on said wall.

8. The apparatus, as recited in claim 3, wherein said device for changing said cusp pattern comprises a device for moving at least one of said magnetic elements.

9. The apparatus, as recited in claim 8, wherein said device for moving at least one of said magnetic elements comprises a device for moving a plurality of said plurality of magnetic elements individually.

10. The apparatus, as recited in claim 9, wherein said device for moving said plurality said plurality of magnetic elements comprises a device for rotating said plurality of magnetic elements in an alternating pattern.

11. The apparatus, as recited in claim 9, wherein said device for moving said plurality of said plurality of said magnetic elements comprises a device for rotating said magnetic elements in a same direction.

12. The apparatus, as recited in claim 8, wherein said device for moving at least one of said magnetic elements comprises a device for moving said array as a unit relative to said process chamber.

13. The apparatus, as recited in claim 12, wherein said device for moving said magnetic array comprises a device for rotating said array around said chamber.

14. The apparatus, as recited in claim 12, wherein said device for moving said magnetic array comprises a device for moving said array closer and farther away from said chamber.

15. The apparatus, as recited in claim 2, wherein said device for changing said cusp pattern comprises a device for moving at least part of said chamber wall within said magnetic field.

16. The apparatus of claim 15 wherein said device for moving at least part of said chamber wall comprises a device for rotating said chamber wall within said magnetic field.

17. The apparatus, as recited in claim 15, wherein said device for moving at least part of said chamber wall comprises a device for moving a part of the chamber wall that is an inner chamber wall forming a liner.

18. The apparatus, as recited in claim 2, wherein said device for changing said cusp pattern comprises a device for moving at least part of a flux plate assembly within said magnetic field.

19. A method for controlling a volume of a plasma while processing a substrate in a process chamber, said chamber defined at least in part by a wall, using a plasma enhanced process, comprising:
producing a magnetic field inside said process chamber with a magnetic array, said magnetic field establishing a magnetic cusp pattern on said wall;
shifting said cusp pattern on said wall;
creating and sustaining a plasma in a plasma region inside said process chamber; and
confining said plasma within a volume defined at least in part by a portion of said wall and said magnetic field.

20. The method, as recited in claim 19, further comprising the step of mounting said substrate on a chuck, so that said substrate is within said plasma region.

21. The method, as recited in claim 20, wherein the magnetic field has an azimuthally symmetric radial gradient.

22. The method, as recited in claim 21, wherein the step of producing said magnetic field comprises the step of providing a plurality of magnetic elements that are disposed around said wall, and wherein said step of shifting said cusp pattern comprises the step of moving at least one of said magnetic elements.

23. The method, as recited in claim 22, wherein the step of moving at least one of said magnetic elements, comprises the step of individually rotating a plurality of magnetic elements in alternating directions.

24. The method, as recited in claim 22, wherein the step of moving at least one of said magnetic elements, comprises the step of individually rotating a plurality of magnetic elements in a same direction.

25. The method, as recited in claim 22, wherein the step of moving at least one of said magnetic elements, comprises moving a plurality of magnetic elements as a single array, which rotates around said chamber.

26. The method, as recited in claim 21, wherein said step of shifting said cusp pattern comprises the step of moving at least part of said chamber wall.

27. The method, as recited in claim 20, wherein said step of shifting said cusp pattern comprises the step of moving at least part of a flux plate assembly.
